(19) United States
(12) Patent Application Publication
(10) Pub. No.: US 2012/0068253 A1
(43) Pub. Date: Mar. 22, 2012

(54) NONVOLATILE SEMICONDUCTOR MEMORY DEVICE AND METHOD FOR MANUFACTURING THE SAME

(75) Inventors: Shigeto Oota, Mie-ken (JP); Masaru Kidoh, Tokyo (JP); Hideaki Aochi, Kanagawa-ken (JP)

(73) Assignee: Kabushiki Kaisha Toshiba, Tokyo (JP)

(21) Appl. No.: 13/052,161

(22) Filed: Mar. 21, 2011

(30) Foreign Application Priority Data
Mar. 23, 2010 (JP) 2010-66191

(51) Int. Cl. H01L 29/78; H01L 21/28

(52) U.S. Cl. 257/324; 438/591; 257/E29.255; 257/E21.209

(57) ABSTRACT

According to one embodiment, a nonvolatile semiconductor memory device includes a memory region and a non-memory region. The memory region includes a stacked structural body, a semiconductor pillar, a memory layer, an inner insulating film and an outer insulating film. The stacked structural body includes a plurality of electrode films stacked alternately along a first direction with a plurality of inter-electrode insulating films. The semiconductor pillar pierces the stacked structural body in the first direction. The memory layer is provided between the semiconductor pillar and each of the plurality of electrode films. The inner insulating film is provided between the memory layer and the semiconductor pillar. The outer insulating film is provided between the memory layer and each of the plurality of electrode films. The non-memory region is provided with the memory region along a second direction orthogonal to the first direction. The non-memory region includes an insulating part.

### CROSS-REFERENCE TO RELATED APPLICATIONS

This application is based upon and claims the benefit of priority from the prior Japanese Patent Application No. 2010-066191, filed on Mar. 23, 2010; the entire contents of which are incorporated herein by reference.

### FIELD

Embodiments described herein relate generally to a nonvolatile semiconductor memory device and a method for manufacturing the same.

### BACKGROUND

Conventional LSI (Large Scale Integration) integrates elements in a two-dimensional plane on a silicon substrate. It is necessary to reduce the dimensions of one element (downscale) to increase the storage capacity in semiconductor memory devices (memory). However, in recent years, such downscaling has become difficult in regard to both technology and cost.

JP-A 2007-320215 (Kokai) discusses a collectively patterned three-dimensionally stacked memory cell. Such a collectively patterned three-dimensionally stacked memory includes a stacked body in which insulating films are alternately stacked with electrode films, silicon pillars piercing the stacked body, and a charge storage layer (a memory layer) provided between the silicon pillars and the electrode films. Thereby, memory cells are provided at the intersections between the silicon pillars and each of the electrode films.

Thus, the three-dimensional collectively patterned memory includes a multilayered structural body in which electrode films used as the gate electrodes are stacked with insulating films.

The multilayered structural body is provided not only in the region of the memory cells but also in a region peripheral to the memory cells. Therefore, parasitic capacitance occurs between the polysilicon and the insulating films included in the multilayered structural body in the region peripheral to the memory cells; and the operations may become unstable in some cases.

### BRIEF DESCRIPTION OF THE DRAWINGS

FIG. 1 is a schematic cross-sectional view illustrating a nonvolatile semiconductor memory device according to a first embodiment;

FIG. 2 is a schematic cross-sectional view illustrating the overall configuration of the nonvolatile semiconductor memory device according to the first embodiment;

FIG. 3 is a schematic perspective view illustrating the configuration of the nonvolatile semiconductor memory device according to the first embodiment;

FIG. 4 is a schematic cross-sectional view illustrating the configuration of a portion of the nonvolatile semiconductor memory device according to the first embodiment;

FIG. 5 is a schematic plan view illustrating the configuration of the electrode film of the nonvolatile semiconductor memory device according to the first embodiment;

FIG. 6 is a schematic cross-sectional view a nonvolatile semiconductor memory device according to a comparative example;

FIG. 7 is a schematic cross-sectional view illustrating a nonvolatile semiconductor memory device according to a second embodiment;

FIG. 8 to FIG. 17 are schematic views illustrating a method for manufacturing the nonvolatile semiconductor memory device according to the third embodiment; and

FIG. 18 is a schematic cross-sectional view illustrating a nonvolatile semiconductor memory device according to a fourth embodiment.

### DETAILED DESCRIPTION

In general, according to one embodiment, a nonvolatile semiconductor memory device includes a memory region and a non-memory region. The memory region includes a stacked structural body, a semiconductor pillar, a memory layer, an inner insulating film and an outer insulating film. The stacked structural body includes a plurality of electrode films stacked alternately along a first direction with a plurality of inter-electrode insulating films. The semiconductor pillar pierces the stacked structural body in the first direction. The memory layer is provided between the semiconductor pillar and each of the plurality of electrode films. The inner insulating film is provided between the memory layer and the semiconductor pillar. The outer insulating film is provided between the memory layer and each of the plurality of electrode films. The non-memory region is provided with the memory region along a second direction orthogonal to the first direction. The non-memory region includes an insulating part provided at a position along the first direction being same as a position of at least one of the electrode films of the stacked structural body.

In general, according to one other embodiment, a nonvolatile semiconductor memory device includes a memory region, a non-memory region and a separation member. The memory region includes a stacked structural body, a semiconductor pillar, a memory layer, an inner insulating film and an outer insulating film. The stacked structural body includes a plurality of electrode films stacked alternately along a first direction with a plurality of inter-electrode insulating films. The semiconductor pillar pierces the stacked structural body in the first direction. The memory layer is provided between the semiconductor pillar and each of the plurality of electrode films. The inner insulating film is provided between the memory layer and the semiconductor pillar. The outer insulating film is provided between the memory layer and each of the plurality of electrode films. The non-memory region is provided with the memory region along a second direction orthogonal to the first direction. The non-memory region includes an inter-layer conductive unit provided at a position along the first direction being same as a position of at least one of the inter-electrode insulating films of the stacked structural body. The separation member is provided between the memory region and the non-memory region to electrically isolate the plurality of electrode films from the inter-layer conductive unit.

In general, according to one embodiment, a method is disclosed for manufacturing a nonvolatile semiconductor memory device. The method can form a stacked structural body on a major surface of a substrate in a first region on the major surface of the substrate and in a second region inside the first region. The stacked structural body includes a plurality of first conductive films alternately stacked with a plurality of first films. The method can form a support member to support the plurality of first conductive films by making a trench along a stacking direction of the stacked structural body at a boundary between the first region and the second region to pierce through to a position lower than an upper face of the first conductive film of a lowermost level of the stacked structural body and by filling an insulating material into the trench. The method can remove the plurality of first films in the second region, oxidize the plurality of first conductive films in the second region. The method can make a through-hole to pierce in the stacking direction in the first region and form an outer insulating film, a memory layer, and an inner insulating film in order on an inner wall of the through-hole.

Various embodiments will be described hereinafter with reference to the accompanying drawings.

The drawings are schematic or conceptual; and the relationships between the thicknesses and widths of portions, the proportional coefficients of sizes among portions, etc., are not necessarily the same as the actual values thereof. Further, the dimensions and the proportional coefficients may be illustrated differently among the drawings, even for identical portions. In the specification and the drawings of the application, components similar to those described in regard to a drawing thereinabove are marked with like reference numerals, and a detailed description is omitted as appropriate.

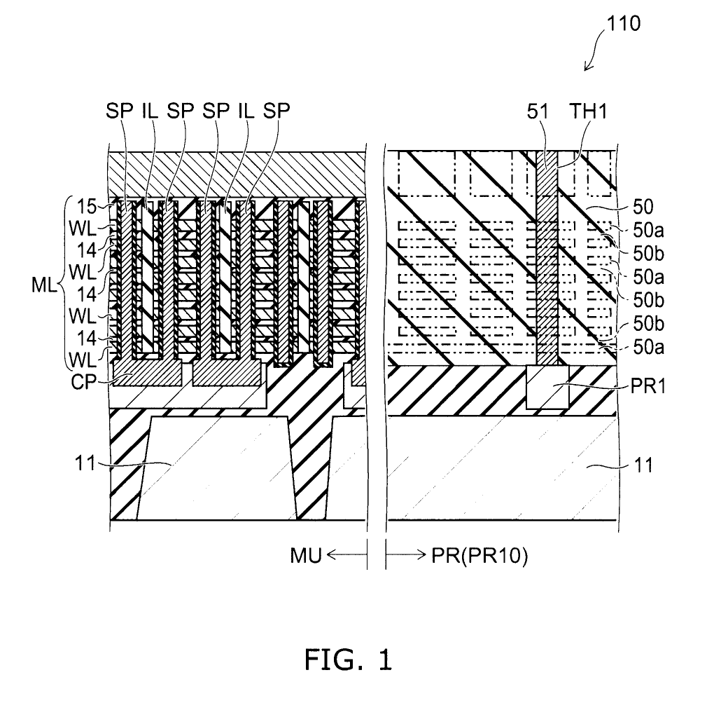

FIG. 1 is a schematic cross-sectional view illustrating a nonvolatile semiconductor memory device according to a first embodiment.

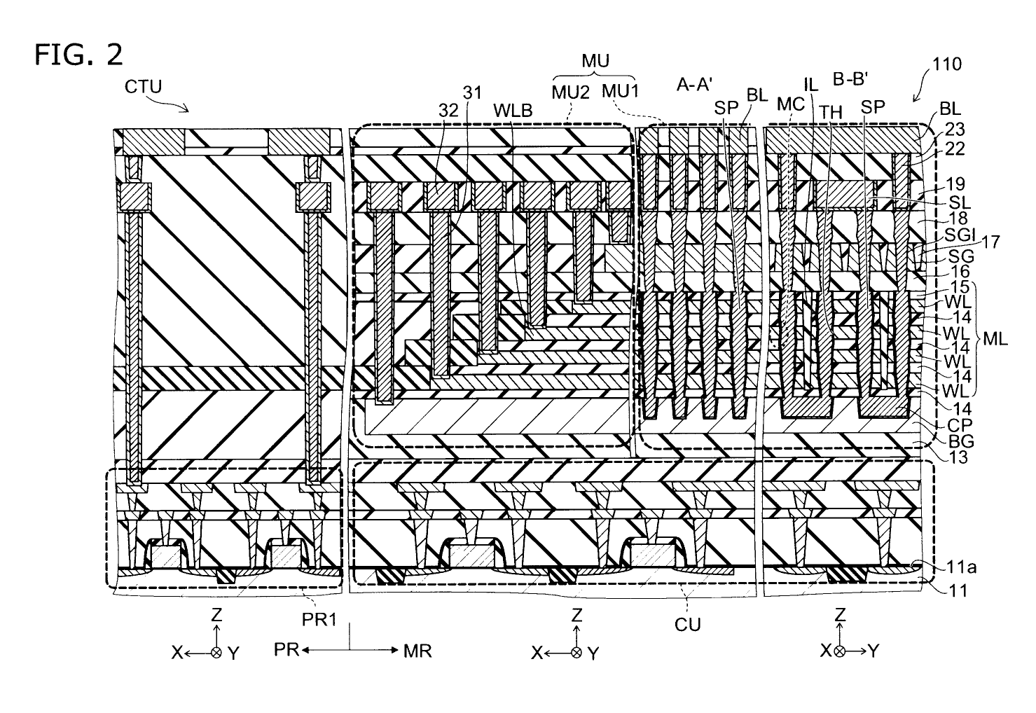

FIG. 2 is a schematic cross-sectional view illustrating the overall configuration of the nonvolatile semiconductor memory device.

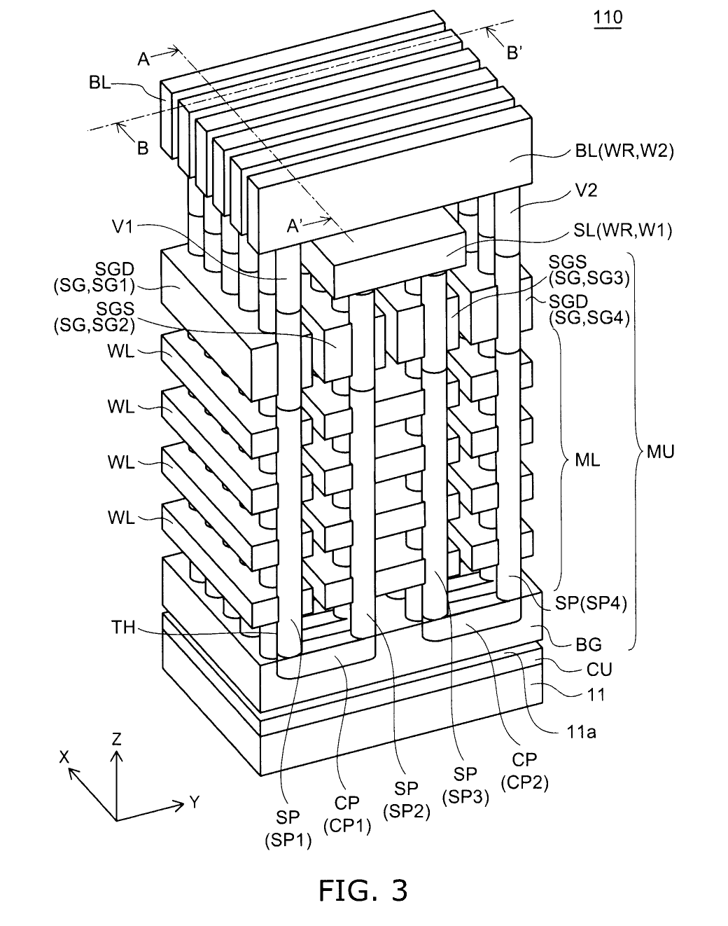

FIG. 3 is a schematic perspective view illustrating the configuration of the nonvolatile semiconductor memory device.

For easier viewing of the drawing in FIG. 3, only the conductive portions are illustrated, and the insulating portions are omitted.

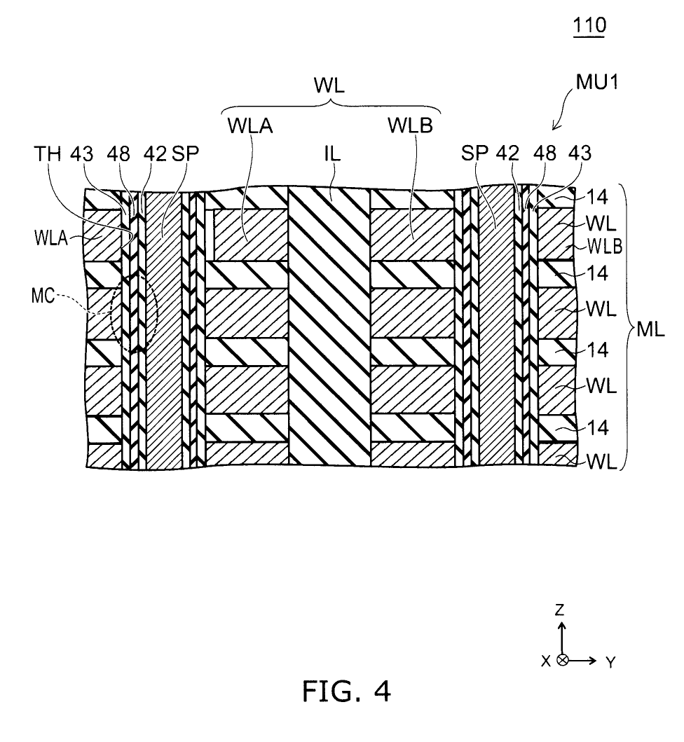

FIG. 4 is a schematic cross-sectional view illustrating the configuration of a portion of the nonvolatile semiconductor memory device.

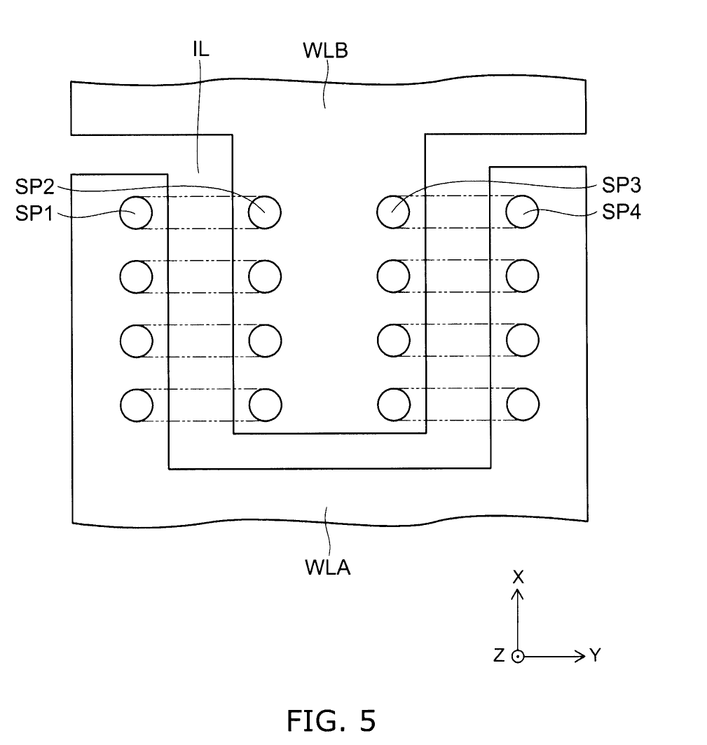

FIG. 5 is a schematic plan view illustrating the configuration of the electrode film of the nonvolatile semiconductor memory device.

First Embodiment

As illustrated in FIG. 1, FIG. 2, and FIG. 3, the nonvolatile semiconductor memory device 110 according to the embodiment includes a memory region MU and a non-memory region PR10. The memory region MU includes: a stacked structural body ML in which multiple electrode films WL and multiple inter-electrode insulating films 14 are stacked alternately along a first direction; and semiconductor pillars SP piercing the stacked structural body ML.

Herein, an XYZ orthogonal coordinate system is introduced for convenience of description in the specification of the application. In this coordinate system, the first direction is taken as a Z-axis direction. A direction perpendicular to the Z-axis direction is taken as a Y-axis direction (a second direction). A direction perpendicular to the Z-axis direction and the Y-axis direction is taken as an X-axis direction (a third direction).

As illustrated in FIG. 4, the memory region MU further includes a charge storage film (a memory layer) 48 provided between the semiconductor pillar SP and each of the multiple electrode films WL, an inner insulating film 42 provided between the charge storage film 48 and the semiconductor pillar SP, and an outer insulating film 43 provided between the charge storage film 48 and each of the multiple electrode films WL.

Memory cells MC are provided at the intersections between the electrode films WL and the semiconductor pillars SP of the stacked structural body ML. In other words, memory cell transistors including the charge storage film 48 are provided in a three-dimensional matrix configuration at the portions where the electrode films WL and the semiconductor pillars SP intersect; and each of the memory cell transistors functions as a memory cell MC to store data by storing charge in the charge storage film 48.

The nonvolatile semiconductor memory device 110 according to the embodiment having the configuration recited above is a three-dimensionally stacked flash memory.

As illustrated in FIG. 1, the non-memory region PR10 is provided with the memory region MU along a direction orthogonal to the first direction. The non-memory region PR10 is provided in, for example, a peripheral region PR which is peripheral with respect to the memory region MU. The non-memory region PR10 may be multiply provided in the peripheral region PR.

The non-memory region PR10 includes an insulating part 50 provided at the same position along the first direction as the position of the stacked structural body ML.

The insulating part 50 includes, for example, multiple first insulating films 50a provided at the same positions along the first direction as the positions of the multiple electrode films WL respectively and second insulating films 50b provided at the same positions along the first direction as the positions of the multiple inter-electrode insulating films 14 respectively.

In other words, as illustrated in FIG. 2, the nonvolatile semiconductor memory device 110 includes the memory region

MU and the peripheral region PR. The peripheral region PR is a region provided in the periphery of the memory region MU. The peripheral region PR includes the non-memory region PR10. The memory region MU is provided on a major surface 11a of a semiconductor substrate 11 made of, for example, monocrystalline silicon.

In the nonvolatile semiconductor memory device 110, in addition to the case where the first insulating films 50a and the second insulating films 50b have a single body, there are cases where the boundary therebetween is easily ascertainable. In other words, as described below, in the case where the insulating material which is the first insulating films 50a is grown to form the second insulating films 50b, the first insulating films 50a and the second insulating films 50b have a single body. On the other hand, for example, in the case where the first insulating films 50a are formed and then the second insulating films 50b are filled subsequently using a separate process (e.g., CVD (Chemical Vapor Deposition)), the first insulating films 50a and the second insulating films 50b are separate entities and the boundary therebetween is easily ascertainable.

If necessary, a through-hole TH1 piercing the insulating part 50 in the first direction is provided in the non-memory region PR10; and a conductive through-member 51 is provided in the interior of the through-hole TH1. The conductive through-member 51 is electrically connected to, for example, a peripheral region circuit PR1 provided on the semiconductor substrate 11 of the non-memory region PR10. The conductive through-member 51 can be utilized as an interconnect for the signal input/output or to set a potential for the peripheral region circuit PR1.

The first insulating films 50a include, for example, thermal oxide films formed by heating the multiple electrode films WL extending from the memory region MU. In the case where the multiple electrode films WL are formed of a material including, for example, polysilicon or amorphous silicon, the multiple electrode films WL become silicon oxide when heated. In the non-memory region PR10, the silicon oxide and the like formed in the positions where the multiple electrode films WL existed become the first insulating films 50a. Depending on the conditions of the heating, the electrode films WL completely become silicon oxide. Also, depending on the conditions of the heating, there are cases where the electrode films WL become silicon oxide in a state in which a portion of the material qualities remains.

In the non-memory region PR10, the silicon oxide and the like formed in the positions where the multiple inter-electrode insulating films 14 existed become the second insulating films 50b. The second insulating films 50b include, for example, a thermal oxide film. In other words, in the case where the electrode films WL become silicon oxide and the like by heating, a state is reached in which the silicon oxide and the like grow to fill between the multiple electrode films WL. This filled silicon oxide and the like become the second insulating films 50b.

There are also cases where the second insulating films 50b are formed by an insulating material being filled between the multiple first insulating films 50a. The filling of the insulating material is performed using, for example, CVD. Thus, the parasitic capacitance is suppressed by the insulating part 50 being formed in the non-memory region PR10; and the nonvolatile semiconductor memory device 110 having high operational stability is provided.

Comparative Example

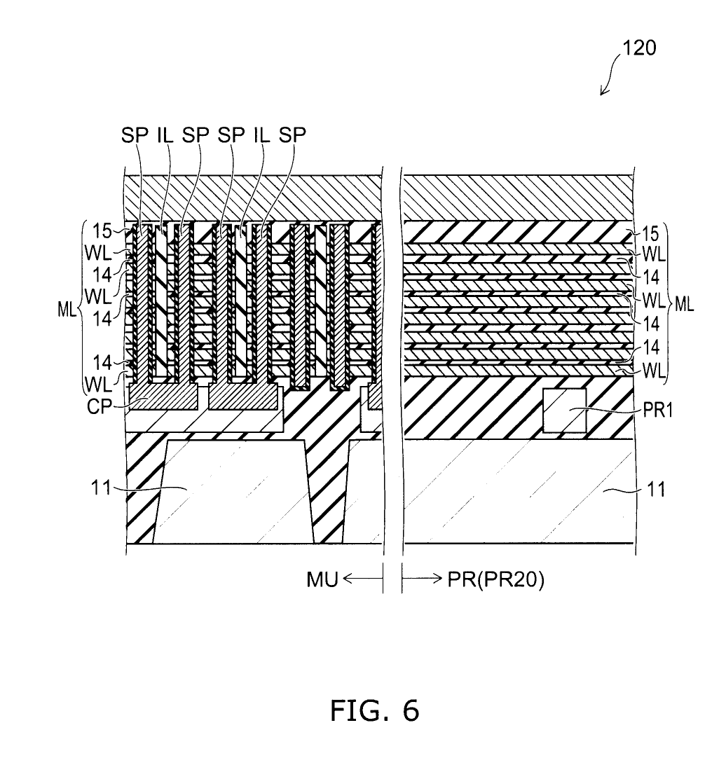

FIG. 6 is a schematic cross-sectional view illustrating the main component of a nonvolatile semiconductor memory device 120 according to a comparative example.

This drawing illustrates the memory region MU and a non-memory region PR20 which is a portion of the peripheral region PR provided in the periphery of the memory region MU.

As described above, the non-memory region PR20 is a portion in which the multiple electrode films WL of the stacked structural body ML extend from the memory region MU. In other words, in the manufacturing of the memory region MU, the memory strings including the semiconductor pillars SP and the like are formed after forming the stacked structural body ML.

At this time, the stacked structural body ML remains in a portion at the periphery of the memory region MU. The non-memory region PR20 is the portion in which the stacked structural body ML remains at the periphery of the memory region MU. The peripheral region circuit PR1 is provided in the semiconductor substrate 11 of the non-memory region PR20.

Here, the stacked structural body ML of the memory region MU includes the multiple electrode films WL and the multiple inter-electrode insulating films 14 stacked alternately in a direction perpendicular to the major surface 11a. The electrode films WL may include, for example, polysilicon. On the other hand, the inter-electrode insulating films 14 may include, for example, silicon oxide. In the case where the stacked structural body ML remains as-is in the non-memory region PR20 as in the nonvolatile semiconductor memory device 120 according to the comparative example illustrated in FIG. 6, a parasitic capacitance occurs in the stacked structure of the multiple electrode films WL and the multiple inter-electrode insulating films 14. This parasitic capacitance affects the operations of the peripheral region circuit PR1.

On the other hand, in the nonvolatile semiconductor memory device 110 according to the first embodiment as illustrated in FIG. 1, the insulating part 50 is provided in the non-memory region PR10 to match the position of at least the stacked structural body ML. That is, the stacked structural body ML, which includes the multiple electrode films WL and the multiple inter-electrode insulating films 14 such as that of the non-memory region PR20 of the nonvolatile semiconductor memory device 120 illustrated in FIG. 6, does not exist in the non-memory region PR10. Accordingly, the occurrence of the parasitic capacitance in the non-memory region PR10 is suppressed.

The non-memory region PR10 is provided in a region where the stacked structural body ML was extending from the memory region MU. Therefore, in the non-memory region PR10, the entirety or a portion of the initially-extended stacked structural body ML becomes the insulating part 50. Thereby, the insulating part 50 includes a portion in which an insulating material is provided to match the position along the first direction of at least one of the electrode films WL of the stacked structural body ML.

For example, in the non-memory region PR10, the inter-electrode insulating films 14 are removed from the stacked structural body ML extending from the memory region MU. Subsequently, the remaining electrode films WL are made into thermal oxide films (e.g., silicon oxide films) such that, for example, the entire region where the multiple electrode films WL existed becomes thermal oxide films. Thereby, in the non-memory region PR10, the first insulating films 50a are provided at the positions where the multiple electrode films WL existed. Also, thermal oxide films growing from the electrode films WL fill between the multiple electrode films WL. These become the second insulating films 50b.

Here, this includes the case where a portion of the multiple electrode films WL does not become an insulating material in the first insulating films 50a in addition to the case where the multiple electrode films WL completely become the insulating material in the first insulating films 50a. In other words, when the electrode films WL are heated to become the oxide films, the oxide films are produced in the surfaces of the electrode films WL; and the electrode films WL themselves also become oxide films. Thereby, the oxide films fill between the mutually adjacent electrode films WL. In such a case, depending on the conditions of the heating, there are cases where the electrode films WL completely become the oxide films and cases where the electrode films WL remain without being oxidized. The insulating part 50 includes both of these cases.

It is desirable for the entire region where the stacked structural body ML existed to become the insulating material in the insulating part 50 to suppress the parasitic capacitance. However, even in the case where a portion of the electrode films WL remains without being oxidized, the spacing of the remaining electrode films WL is wider than the spacing of the electrode films WL included in the initial stacked structural body ML. Accordingly, the suppression effect of the parasitic capacitance can be sufficiently realized.

Thereby, the operational stability of the nonvolatile semiconductor memory device 110 can be increased.

Other than silicon oxide, the insulating material of the insulating part 50 may include silicon nitride and the like. In the case where silicon nitride is used as insulating part 50, it is sufficient to use CVD and the like to fill the silicon nitride into the portion from which the inter-electrode insulating films 14 are removed.

An example of the configuration of the nonvolatile semiconductor memory device 110 will now be described further.

The memory region MU includes a matrix memory cell unit MU1, which includes the multiple memory cell transistors, and an interconnect connection unit MU2, which connects the interconnects of the matrix memory cell unit MU1.

FIG. 4 illustrates the configuration of the matrix memory cell unit MU1.

Namely, a portion of the cross section along A-A′ of FIG. 3 and a portion of the cross section along line B-B′ of FIG. 3 are illustrated as the matrix memory cell unit MU1 in FIG. 4.

In the matrix memory cell unit MU1 as illustrated in FIG. 3 and FIG. 4, the stacked structural body ML is provided on the major surface 11a of the semiconductor substrate 11. The stacked structural body ML includes the multiple electrode films (the electrode members) WL and the multiple inter-electrode insulating films 14 stacked alternately in a direction perpendicular to the major surface 11a.

The stacking direction of the electrode films WL and the inter-electrode insulating films 14 of the stacked structural body ML is the first direction. In other words, the electrode films WL and the inter-electrode insulating films 14 are provided parallel to the major surface 11a. The electrode films WL are divided into units of, for example, erasing blocks.

FIG. 4 illustrates the configuration of the matrix memory cell unit MU1 and corresponds to, for example, a portion of the cross section along line B-B′ of FIG. 3.

As illustrated in FIG. 3 and FIG. 4, the memory region MU of the nonvolatile semiconductor memory device 110 includes the stacked structural body ML recited above, the semiconductor pillar SP (a first semiconductor pillar SP1) which is a semiconductor portion piercing the stacked structural body ML in the first direction, the charge storage film 48, the inner insulating film (the first insulating film) 42, the outer insulating film (the second insulating film) 43, and an interconnect WR.

The charge storage film 48 is provided between the semiconductor pillar SP and each of the electrode films WL. The inner insulating film 42 is provided between the charge storage film 48 and the semiconductor pillar SP. The outer insulating film 43 is provided between the charge storage film 48 and each of the electrode films WL. The interconnect WR is electrically connected to one end of the semiconductor pillar SP.

In other words, the outer insulating film 43, the charge storage film 48, and the inner insulating film 42 are formed in this order on the wall face of the interior of a through-hole TH piercing the stacked structural body ML in the first direction; and a semiconductor is filled into the remaining space to form the semiconductor pillar SP.

Accordingly, a memory layer 4 of the memory cell MC at the position of the electrode film WL functions as a memory region; and multiple memory regions are provided along the extension direction of the charge storage film 48.

The inner insulating film 42 functions as a tunneling insulating film of the memory cell transistor of the memory cell MC. On the other hand, the outer insulating film 43 functions as a blocking insulating film of the memory cell transistor of the memory cell MC. The inter-electrode insulating film 14 functions as an inter-layer insulating film that insulates the electrode films WL from each other.

The electrode film WL may include any electrically conductive material. For example, amorphous silicon or polysilicon provided with an electrical conductivity by introducing an impurity may be used; or a metal, an alloy, etc., also may be used. A prescribed electrical signal is applied to the electrode film WL; and the electrode film WL functions as a word line of the nonvolatile semiconductor memory device 110.

The inter-electrode insulating film 14, the inner insulating film 42, and the outer insulating film 43 may include, for example, silicon oxide films. The inter-electrode insulating film 14, the inner insulating film 42, and the outer insulating film 43 may be single-layer films or stacked films.

The charge storage film 48 may include, for example, a silicon nitride film; and the charge storage film 48 functions as a portion configured to store information by storing or emitting a charge by an electric field applied between the semiconductor pillar SP and the electrode film WL. The charge storage film 48 may be a single-layer film or a stacked film.

As described below, the inter-electrode insulating film 14, the inner insulating film 42, the charge storage film 48, and the outer insulating film 43 are not limited to the materials described above; and any material may be used.

Although the case is illustrated in FIG. 2 and FIG. 3 in which the stacked structural body ML includes four layers of the electrode films WL, any number of electrode films WL may be provided in the stacked structural body ML.

In the nonvolatile semiconductor memory device 110 of the specific example as illustrated in FIG. 2, two of the semiconductor pillars SP are connected by a connection portion CP (a connection portion semiconductor layer).

In other words, the memory region MU further includes a second semiconductor pillar SP2 (the semiconductor pillar SP) and a first connection portion CP1 (the connection portion CP).

The second semiconductor pillar SP2 is adjacent to the first semiconductor pillar SP1 (the semiconductor pillar SP) in, for example, the second direction and pierces the stacked structural body ML in the first direction. The first connection portion CP1 electrically connects the first semiconductor pillar SP1 to the second semiconductor pillar SP2 on the same first-direction side (the semiconductor substrate 11 side). The first connection portion CP1 is provided to extend in the second direction. The first connection portion CP1 includes the same material as the first and second semiconductor pillars SP1 and SP2.

In other words, a back gate BG (a connection portion conductive layer) is provided on the major surface 11a of the semiconductor substrate 11 with an inter-layer insulating film 13 interposed therebetween. Then, a trench (a trench CTR described below) is provided in a portion of the back gate BG opposing the first and second semiconductor pillars SP1 and SP2; the outer insulating film 43, the charge storage film 48, and the inner insulating film 42 are formed in the interior of the trench; and the connection portion CP made of a semiconductor is filled into the remaining space. The formation of the outer insulating film 43, the charge storage film 48, the inner insulating film 42, and the connection portion CP in the trench recited above is performed collectively and simultaneously with the formation of the outer insulating film 43, the charge storage film 48, the inner insulating film 42, and the semiconductor pillar SP in the through-hole TH. Thus, the back gate BG is provided to oppose the connection portion CP.

Thereby, a semiconductor pillar having a U-shaped configuration is formed of the first and second semiconductor pillars SP1 and SP2 and the connection portion CP; and this forms a NAND string having a U-shaped configuration.

Although the connection portion CP has a function of electrically connecting the first and second semiconductor pillars SP1 and SP2, the connection portion CP also can be utilized as one memory cell. Thereby, the memory bits also can be increased. Hereinbelow, the case is described where the connection portion CP electrically connects the first and second semiconductor pillars SP1 and SP2 and is not used as a memory region. In such a case, although the charge storage film 48 opposing the connection portion CP does not function as a memory region, the portion of the charge storage film 48 opposing the connection portion CP also is referred to as a memory layer to simplify the description.

As illustrated in FIG. 2 and FIG. 3, the end of the first semiconductor pillar SP1 opposite to the first connection portion CP1 is connected to a bit line BL (a second interconnect W2); and the end of the second semiconductor pillar SP2 opposite to the first connection portion CP1 is connected to a source line SL (a first interconnect W1). The semiconductor pillar SP is connected to the bit line BL by a via V1 and a via V2. The interconnect WR includes the first interconnect W1 and the second interconnect W2.

In the specific example, the bit line BL extends in the second direction; and the source line SL extends in the third direction.

A drain-side selection gate electrode SGD (a first selection gate electrode SG1, i.e., a selection gate electrode SG) is provided to oppose the first semiconductor pillar SP1 between the stacked structural body ML and the bit line BL; and a source-side selection gate electrode SGS (a second selection gate electrode SG2, i.e., the selection gate electrode SG) is provided to oppose the second semiconductor pillar SP2 between the stacked structural body ML and the bit line BL. Thereby, the desired data can be programmed to or read from any memory cell MC of any semiconductor pillar SP.

The selection gate electrode SG may include any electrically conductive material, e.g., polysilicon or amorphous silicon. In the specific example, the selection gate electrode SG is divided in the second direction and has band configurations extending along the third direction.

As illustrated in FIG. 2, an inter-layer insulating film 15 is provided in the uppermost portion of the stacked structural body ML (on the side most distal to the semiconductor substrate 11). Then, an inter-layer insulating film 16 is provided on the stacked structural body ML; the selection gate electrode SG is provided thereon; and an inter-layer insulating film 17 is provided between the selection gate electrodes SG. Then, a through-hole is provided in the selection gate electrode SG; a selection gate insulating film SGI of the selection gate transistor is provided on the inner side face thereof; and a semiconductor is filled inside. The semiconductor is linked to the semiconductor pillar SP. In other words, the memory region MU further includes the selection gate electrode SG stacked on the stacked structural body ML in the first direction and pierced by the semiconductor pillar SP on the side of the interconnect WR (at least one selected from the source line SL and the bit line BL).

Then, an inter-layer insulating film 18 is provided on the inter-layer insulating film 17; the source line SL and a via 22 (the vias V1 and V2) are provided thereon; and an inter-layer insulating film 19 is provided around the source line SL. Then, an inter-layer insulating film 23 is provided on the source line SL; and the bit line BL is provided thereon. The bit line BL has a band configuration along the second direction.

The inter-layer insulating films 15, 16, 17, 18, 19, and 23 and the selection gate insulating film SGI may include, for example, silicon oxide.

Herein, “semiconductor pillar SP” is used to refer to all of the semiconductor pillars or any semiconductor pillar multiply provided in the nonvolatile semiconductor memory device 110; and “nth semiconductor pillar SPn” (n being any integer not less than 1) is used to refer to a designated semiconductor pillar when describing the relationship among semiconductor pillars, etc.

As illustrated in FIG. 5, for the electrode films WL, the electrode films corresponding to the semiconductor pillars SP(4m+1) and SP(4m+4) have a common connection to form an electrode film WLA, where m is an integer not less than 0 and n is (4m+1) and (4m+4); and the electrode films corresponding to the semiconductor pillars SP(4m+2) and SP(4m+3) have a common connection to form an electrode film WLB, where n is (4m+2) and (4m+3). In other words, the electrode films WL have a configuration in which the electrode film WLA and the electrode film WLB are combined with each other in a comb teeth configuration opposing in the third direction.

As illustrated in FIG. 4 and FIG. 5, the electrode film WL is divided by an insulating layer IL; and the electrode film WL is divided into the first region (the electrode film WLA) and the second region (the electrode film WLB).

As in the interconnect connection unit MU2 illustrated in FIG. 2, the electrode film WLB is connected at one third-direction end to a word interconnect 32 by a via plug 31 and is electrically connected to, for example, a drive circuit provided in the semiconductor substrate 11. Similarly, the electrode film WLA is connected at the other third-direction end to a word interconnect by a via plug and is electrically connected to the drive circuit. In other words, the length in the third direction of each of the multiple electrode films WL (the electrode film WLA and the electrode film WLB) stacked in the first direction changes in a stairstep configuration; and each of the multiple electrode films WL is electrically connected to the drive circuit at the one third-direction end by the electrode film WLA and at the other third-direction end by the electrode film WLB.

Then, as illustrated in FIG. 3, the memory region MU may further include a third semiconductor pillar SP3 (the semiconductor pillar SP), a fourth semiconductor pillar SP4 (the semiconductor pillar SP), and a second connection portion CP2 (the connection portion CP).

The third semiconductor pillar SP3 is adjacent to the second semiconductor pillar SP2 in the second direction on the side of the second semiconductor pillar SP2 opposite to the first semiconductor pillar SP1 and pierces the stacked structural body ML in the first direction. The fourth semiconductor pillar SP4 is adjacent to the third semiconductor pillar SP3 in the second direction on the side of the third semiconductor pillar SP3 opposite to the second semiconductor pillar SP2 and pierces the stacked structural body ML in the first direction.

The second connection portion CP2 electrically connects the third semiconductor pillar SP3 to the fourth semiconductor pillar SP4 on the same first-direction side (the same side as the first connection portion CP1). The second connection portion CP2 extending in the second direction is provided to oppose the back gate BG.

The charge storage film 48 is provided also between the third semiconductor pillar SP3 and each of the electrode films WL, between the fourth semiconductor pillar SP4 and each of the electrode films WL, and between the back gate BG and the second connection portion CP2. The inner insulating film 42 is provided also between the charge storage film 48 and the third semiconductor pillar SP3, between the charge storage film 48 and the fourth semiconductor pillar SP4, and between the charge storage film 48 and the second connection portion CP2. The outer insulating film 43 is provided also between the charge storage film 48 and each of the electrode films WL and between the charge storage film 48 and the back gate BG.

The source line SL is connected to a third end portion on the side of the third semiconductor pillar SP3 opposite to the second connection portion CP2. The bit line BL is connected to a fourth end portion on the side of the fourth semiconductor pillar SP4 opposite to the second connection portion CP2.

The source-side selection gate electrode SGS (a third selection gate electrode SG3, i.e., the selection gate electrode SG) is provided to oppose the third semiconductor pillar SP3; and the drain-side selection gate electrode SGD (a fourth selection gate electrode SG4, i.e., the selection gate electrode SG) is provided to oppose the fourth semiconductor pillar SP4.

Second Embodiment

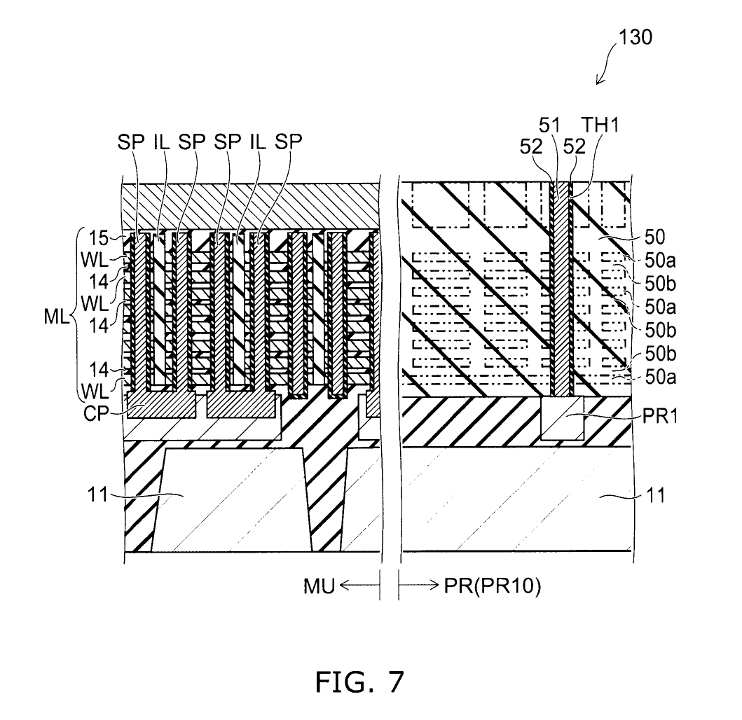

FIG. 7 is a schematic cross-sectional view illustrating the main component of a nonvolatile semiconductor memory device 130 according to a second embodiment.

In the nonvolatile semiconductor memory device 130, the non-memory region PR10 includes the conductive through-member 51 piercing the insulating part 50 in the Z-axis direction and an insulating film 52 provided between the conductive through-member 51 and the inner wall of the through-hole TH1.

Herein, the insulating part 50 includes the first insulating films 50a in which the electrode films WL of the initial stacked structural body ML have become the insulating material. In the insulating part 50, there are cases where a gap occurs between the mutually adjacent electrode films WL when the electrode films WL become the insulating material that becomes the first insulating films 50a. It is conceivable that the material of the conductive through-member 51 may penetrate into such a gap when the conductive through-member 51 is filled into the through-hole TH1 provided in the insulating part 50 in which such a gap occurs. Therefore, the insulating film 52 is provided on the inner wall of the through-hole TH1 such that the gap recited above is not exposed at the through-hole TH1.

The conductive through-member 51 is filled into the through-hole TH1 with the insulating film 52 interposed therebetween. The insulating film 52 performs the role of preventing the material of the conductive through-member 51 from penetrating into the gap.

The insulating film 52 may include any insulating material, e.g., silicon oxide or silicon nitride. Thereby, a nonvolatile semiconductor memory device having high operational stability can be stably manufactured.

Third Embodiment

A third embodiment is a method for manufacturing the nonvolatile semiconductor memory device 110.

In the method for manufacturing the nonvolatile semiconductor memory device, the stacked structural body ML including the multiple first conductive films (the electrode films WL) stacked alternately with the multiple first films on the major surface 11a of a substrate (e.g., the semiconductor substrate 11) is formed in a first region on the major surface 11a of the semiconductor substrate 11 and a second region inside the first region; a trench is made along the stacking direction (the first direction) of the stacked structural body ML at the boundary between the first region and the second region to pierce through to a position lower than at least the upper face of the first conductive film of the lowermost level of the stacked structural body ML; a support member is filled into the trench to support the multiple first conductive films; the multiple first films are removed from the second region; the multiple first conductive films of the second region are oxidized; a through-hole TH piercing the stacked structural body ML in the first direction is made in the first region; and the outer insulating film 43, the charge storage film 48, and the inner insulating film 42 are formed in order on the inner wall of the through-hole TH.

Herein, the region used as the memory region MU is the first region; and the region used as the non-memory region PR10 is the second region.

A specific manufacturing method will now be described based on the drawings.

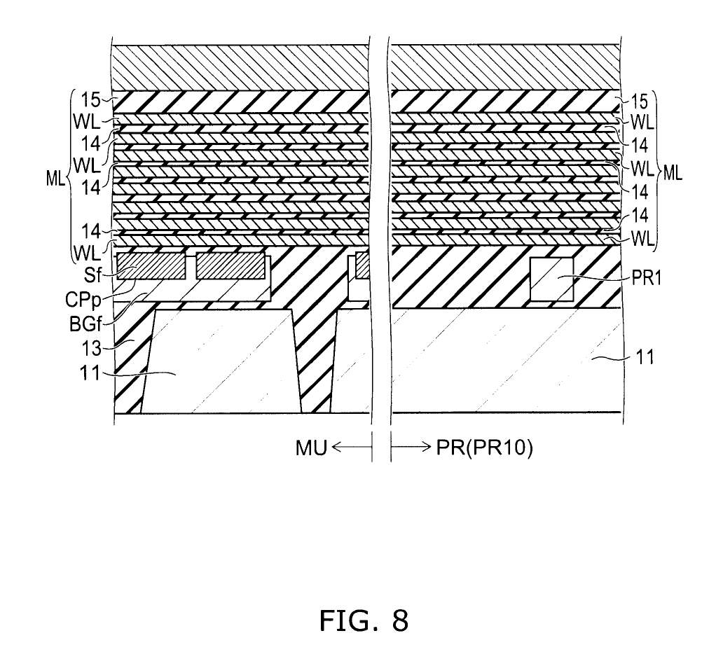

FIG. 8 to FIG. 17 are schematic views illustrating the method for manufacturing the nonvolatile semiconductor memory device according to the third embodiment.

First, as illustrated in FIG. 8, a silicon oxide film used to form the inter-layer insulating film 13 is deposited with a thickness of, for example, 100 nm on the semiconductor substrate 11 made of, for example, silicon; and a conductive film BGf used to form the back gate BG is deposited with a thickness of, for example, 200 nm. The conductive film BGf may include, for example, As-doped amorphous silicon, P-doped amorphous silicon, etc. Subsequently, a trench pattern CPp, into which the semiconductor connection portion CP is formed, is made in the conductive film BGf using lithography and RIE (Reactive Ion Etching); and a sacrificial layer Sf made of a silicon nitride film is filled into the trench pattern CPp.

On the other hand, if necessary, the peripheral region circuit PR1 including transistors and the like may be formed on the semiconductor substrate 11 with the inter-layer insulating film 13 interposed therebetween in the non-memory region PR10 disposed in the periphery of the memory region MU. The peripheral region circuit PR1 is formed in the manufacturing method.

Subsequently, the inter-electrode insulating films 14, i.e., the first films, are deposited alternately with the electrode films WL for the desired number of repetitions on the conductive film BGf, the sacrificial layer Sf, and the peripheral region circuit PR1; and the inter-layer insulating film 15 is deposited thereon. The conductive film BGf may include, for example, As-doped amorphous silicon, P-doped amorphous silicon, etc. Thereby, the stacked structural body ML is formed. The first region is the region on the semiconductor substrate 11 used as the memory region MU where the stacked structural body ML is formed; and the second region is the region on the semiconductor substrate 11 used as the non-memory region PR10 where the stacked structural body ML is formed. Herein, the inter-layer insulating film 15 is taken to be included in the stacked structural body ML.

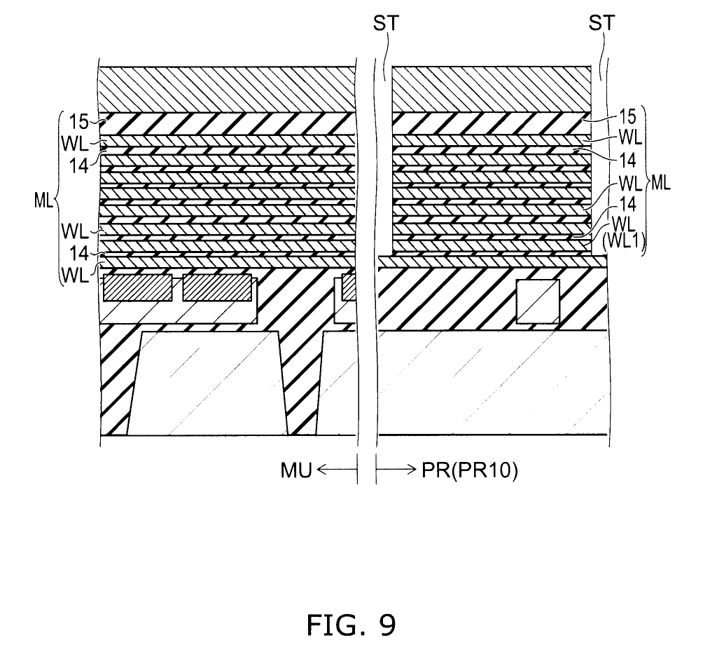

Then, as illustrated in FIG. 9, a trench ST is made at the boundary between the memory region MU and the non-memory region PR10. The trench ST is provided using lithography and RIE. The trench ST is carved through to a position lower than the upper face of an electrode film WL1 of the lowermost level of the stacked structural body ML. The trench ST is made to surround the non-memory region PR10 along directions (the X-Y axis directions) perpendicular to the first direction (the Z-axis direction).

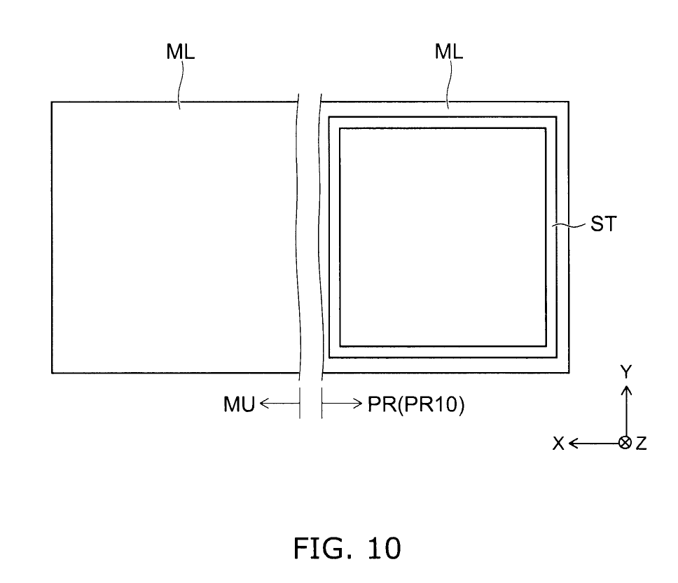

FIG. 10 is a schematic plan view along the X-Y axis directions of the stacked structural body ML. This drawing illustrates the state in which the trench ST is provided along the X-Y axis directions to surround the non-memory region PR10 of the stacked structural body ML. The trench ST may be made to surround the entirety or a portion of the non-memory region PR10. Although an example is illustrated in this drawing in which the trench ST surrounds in a rectangle along the X-Y axis directions, shapes other than a rectangle may be used.

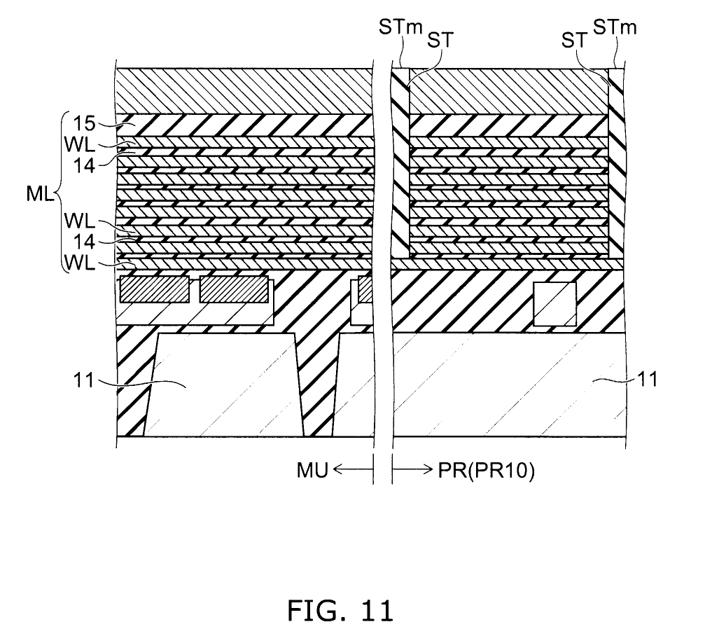

Then, as illustrated in FIG. 11, an insulating material is filled into the trench ST to form a support member STm to support the multiple electrode films WL. Here, the support member STm includes a material that is not etched when etching the inter-electrode insulating films 14 in subsequent processes. The support member STm may include, for example, silicon nitride.

In the case where polysilicon doped with B (boron) is used as the electrode films WL and undoped polysilicon is used as the inter-electrode insulating films 14, silicon oxide, for example, may be used as the support member STm filled into the trench ST.

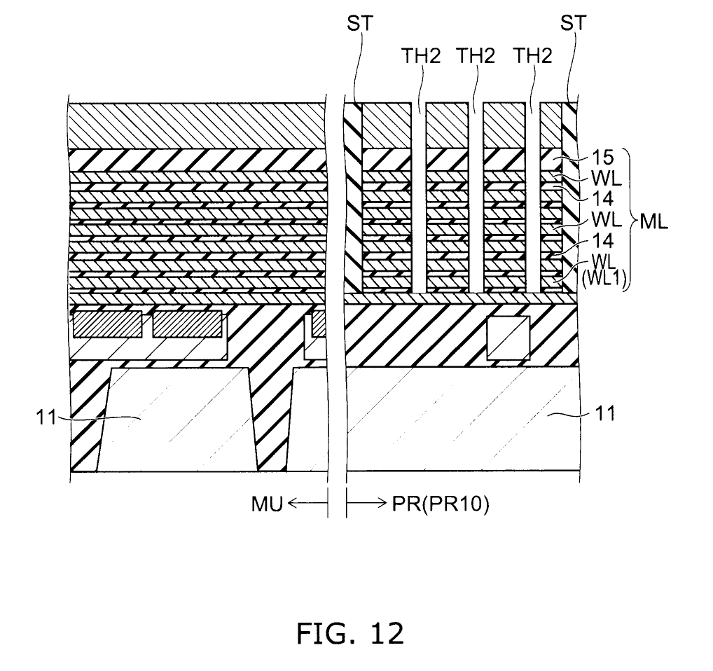

Then, as illustrated in FIG. 12, a through-hole TH2 is made inside the region surrounded by the trench ST. The through-hole TH2 is made to the same depth as the trench ST. The through-hole TH2 is provided using lithography and RIE. The through-hole TH2 illustrated in FIG. 12 is carved to the upper face of the electrode film WL1 of the lowermost level of the stacked structural body ML.

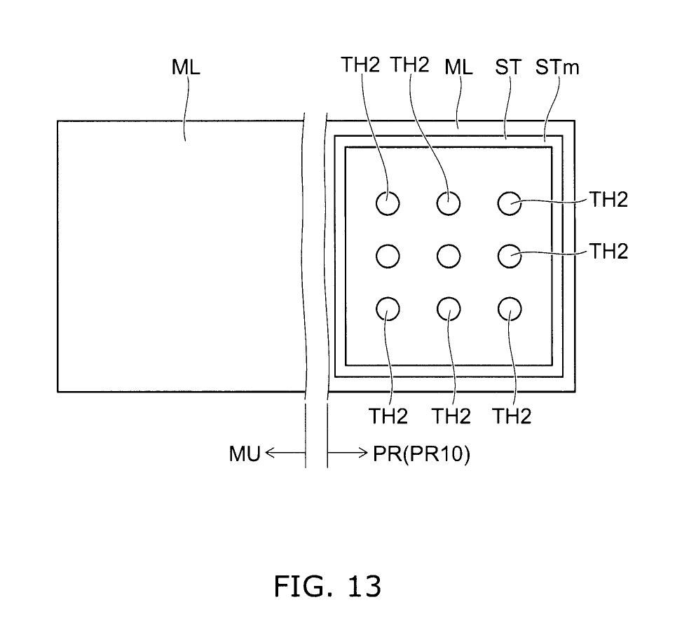

FIG. 13 is a schematic plan view of the stacked structural body ML along the X-Y axis directions.

This drawing illustrates the state in which the through-hole TH2 is made inside the region surrounded by the trench ST in the non-memory region PR10 of the stacked structural body ML. The through-hole TH2 is, for example, multiply made inside the region surrounded by the trench ST. In this drawing, three-by-three through-holes TH2 are formed for a total of nine through-holes TH2. Other than round holes such as those illustrated in this drawing, the through-hole TH2 may have an appropriate configuration such as a rectangular hole, a polygonal hole, an oval hole, an elliptical hole, etc.

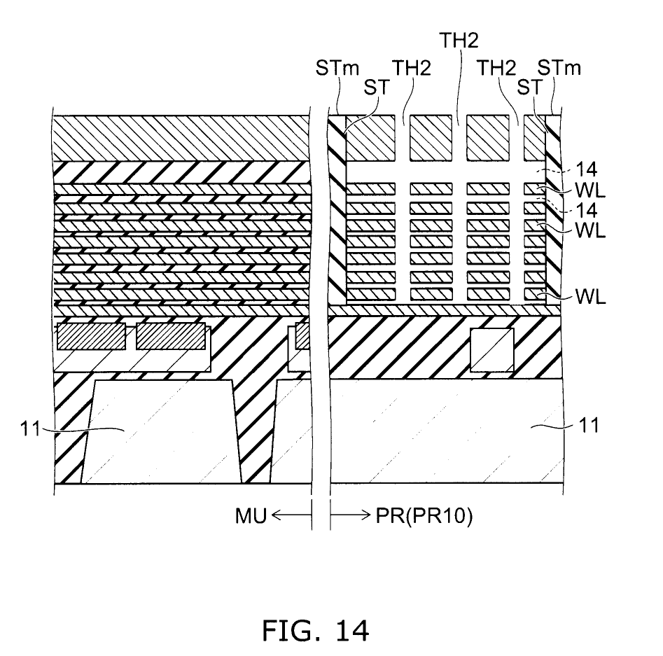

Then, as illustrated in FIG. 14, the inter-electrode insulating films 14 of the stacked structural body ML of the non-memory region PR10 are removed. For example, an etchant that can etch the inter-electrode insulating films 14 from the through-holes TH2 is poured and the inter-electrode insulating films 14 inside the region surrounded by the trench ST are removed by etching. Dilute hydrofluoric acid, for example, may be used as the etchant in the case where silicon oxide is used as the inter-electrode insulating films 14. In this etching, only the inter-electrode insulating films 14 are etched; and the support member STm filled into the trench ST is not etched.

The inter-electrode insulating films 14 may be removed using an alkaline etchant such as, for example, trimethyl-2 hydroxyethyl ammonium hydroxide in the case where polysilicon doped with B (boron) is used as the electrode films WL, undoped polysilicon is used as the inter-electrode insulating films 14, and silicon oxide is used as the support member STm filled into the trench ST. Thereby, the support member STm is not etched; and only the inter-electrode insulating films 14 made of the undoped polysilicon are etched.

When the inter-electrode insulating films 14 are removed, a space forms between the multiple electrode films WL. In such a case, the support member STm inside the trench ST that remains without being etched performs the role of a post and prevents the multiple electrode films WL from collapsing or being crushed.

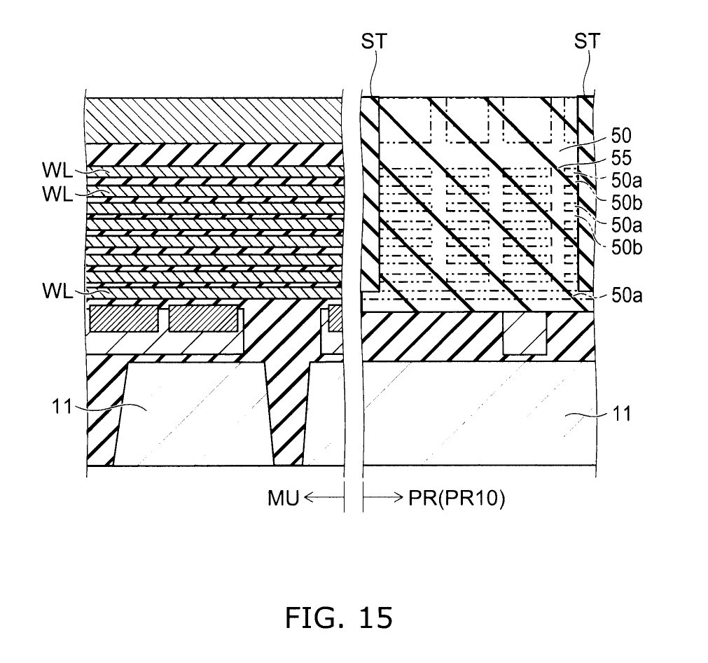

Then, as illustrated in FIG. 15, the electrode films WL are heated after the inter-electrode insulating films 14 are removed to form thermal oxide films. Thereby, the insulating part 50 is formed.

Here, in the case where the electrode films WL are polysilicon or amorphous silicon, silicon oxide films 55 are formed by the heat treatment. In other words, the electrode films WL become the silicon oxide films 55 due to the heat treatment. The silicon oxide films 55 also grow on the surfaces of the electrode films WL.

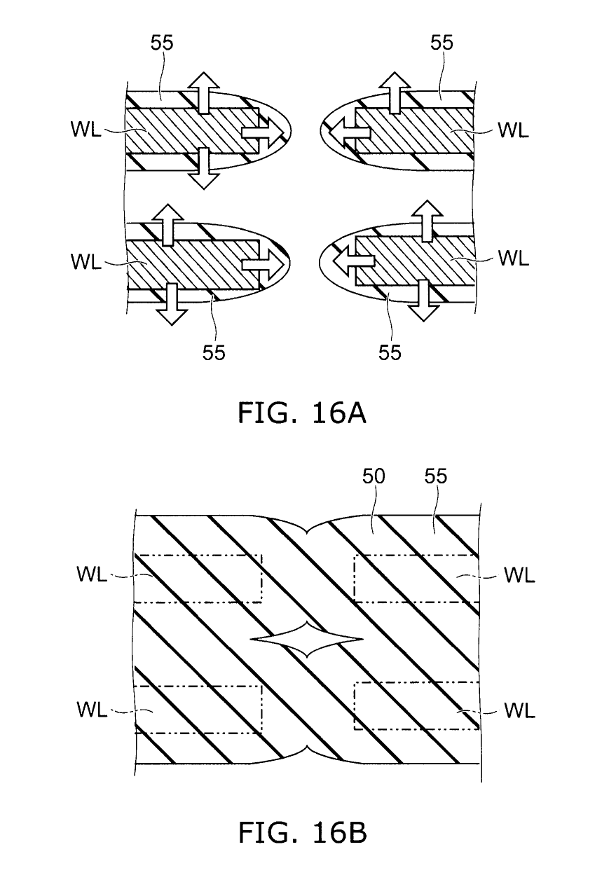

FIG. 16A and 16B are schematic cross-sectional views illustrating the formation of the silicon oxide films 55.

Namely, FIG. 16A illustrates a state partway through the formation of the silicon oxide films 55; and FIG. 16B illustrates a state in which the space between the electrode films WL is filled with the silicon oxide films 55.

The silicon oxide films 55 are formed in the surfaces of the electrode films WL by the heat treatment in the case where the electrode films WL include, for example, polysilicon or amorphous silicon. The silicon oxide films 55 are formed by the material of the electrode films WL bonding with oxygen. Accordingly, as illustrated in FIG. 16A, the silicon oxide films 55 are formed by the electrode films WL being oxidized and grow outward from the surfaces of the electrode films WL.

Then, as the growth of the silicon oxide films 55 progresses as illustrated in FIG. 16B, a state is reach in which the silicon oxide films 55 are filled between the adjacent electrode films WL. Depending on the conditions of the heat treatment, the electrode films WL completely become the silicon oxide films 55; and the insulating part 50 is formed in the non-memory region PR10 in which the silicon oxide film 55 is filled at the same position along the first direction as the position of at least one of the electrode films WL of the stacked structural body ML. Other than the case where the silicon oxide films 55 are formed by the heat treatment, there are cases where the insulating part 50 includes the inter-layer insulating films 13 formed as a single body with the silicon oxide films 55.

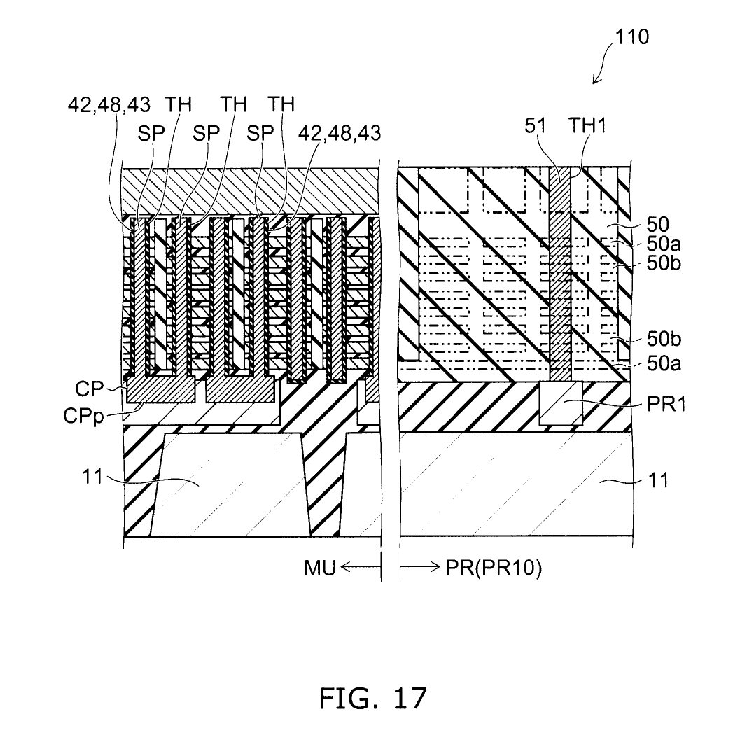

Continuing as illustrated in FIG. 17, the memory strings are formed in the memory region MU of the stacked structural body ML. In other words, the through-holes TH are formed in the memory region MU of the stacked structural body ML using photolithography and RIE. The through-holes TH are made to reach the position of the sacrificial layer Sf filled into the trench pattern CPp of the semiconductor connection portions CP. Subsequently, the sacrificial layer Sf is etched from the through-holes TH; and the through-holes TH communicate with the trench pattern CPp. Then, the outer insulating film 43, the charge storage film 48, and the inner insulating film 42 are formed in order from the inner wall of the through-holes TH and the trench pattern CPp; and the semiconductor pillars SP are filled. Thereby, the memory strings are formed.

If necessary, a through-hole TH1 is made in the non-memory region PR10 of the stacked structural body ML and the conductive through-member 51 is formed in the through-hole TH1. Thereby, an electrical connection can be obtained with the peripheral region circuit PR1 provided on the semiconductor substrate 11 of the non-memory region PR10.

Thereby, the nonvolatile semiconductor memory device 110 is fabricated.

In the nonvolatile semiconductor memory device 110 thus fabricated, the insulating part 50 is provided in the non-memory region PR10; and the stacked structural body ML such as that of the nonvolatile semiconductor memory device 120 does not exist. Accordingly, in the nonvolatile semiconductor memory device 110, the occurrence of the parasitic capacitance due to the stacked structural body ML in the non-memory region PR10 is suppressed.

Fourth Embodiment

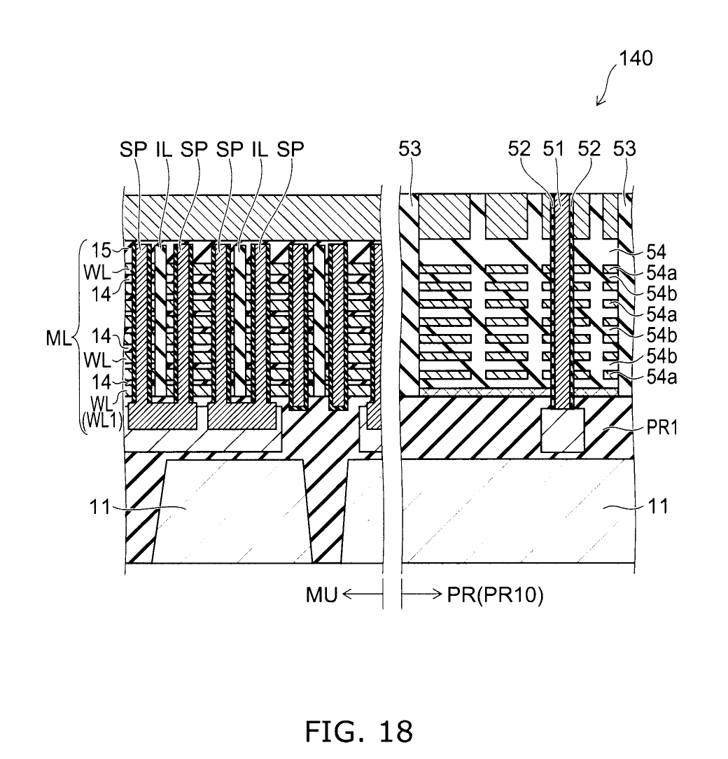

FIG. 18 is a schematic cross-sectional view illustrating a nonvolatile semiconductor memory device 140 according to a fourth embodiment.

The nonvolatile semiconductor memory device 140 includes an inter-layer conductive unit 54 provided in the non-memory region PR10 at the same position along the first direction as the position of at least one of the inter-electrode insulating films 14 of the stacked structural body ML and a separation member 53 provided between the memory region MU and the non-memory region PR10 to electrically isolate the multiple electrode films WL from the inter-layer conductive unit 54.

The separation member 53 is provided between the memory region MU and the non-memory region PR10 to reach the position of the electrode film WL1 of the lowermost level of the stacked structural body ML. The separation member 53 includes an insulating material such as, for example, silicon oxide or silicon nitride. The separation member 53 performs the role of electrically isolating the multiple electrode films WL of the memory region MU from the multiple electrode films WL of the non-memory region PR10. Accordingly, it is desirable for the separation member 53 to be formed to surround along the X-Y axis directions as does the trench ST.

The inter-layer conductive unit 54 includes: multiple first conductive films 54a provided at the same positions along the first direction as the positions of the multiple electrode films WL respectively; and second conductive films 54b provided at the same positions along the first direction as the positions of the multiple inter-electrode insulating films 14 respectively. For example, the inter-layer conductive unit 54 may include an electrically conductive material including polysilicon or amorphous silicon. In the nonvolatile semiconductor memory device 140, the occurrence of the parasitic capacitance is suppressed more than in the nonvolatile semiconductor memory device 120 according to the comparative example because the inter-layer conductive unit 54 is provided in the non-memory region PR10.

In the nonvolatile semiconductor memory device 140, to provide the conductive through-member 51 to obtain an electrical connection with the peripheral region circuit PR1 in the non-memory region PR10, the insulative insulating film 52 may be provided between the inter-layer conductive unit 54 and the conductive through-member 51. Thereby, shorts between the inter-layer conductive unit 54 and the conductive through-member 51 can be prevented.

The fabrication of the nonvolatile semiconductor memory device 140 is as follows.

In the process illustrated in FIG. 9, the trench ST is made to reach the electrode film WL of the lowermost level of the stacked structural body ML. Subsequently, an insulating material is filled into the trench ST. The insulating material filled into the trench ST is used as the separation member 53.

By providing the separation member 53, electrical connections from the non-memory region PR10 to the multiple electrode films WL of the memory region MU are shielded. In the non-memory region PR10, the first conductive films 54a are the portions of the non-memory region PR10 that are shielded by the separation member 53 from being electrically connected to the electrode films WL.

In this state, the through-holes TH2 illustrated in FIG. 12 are made and the inter-electrode insulating films 14 are removed by the etchant.

Subsequently, an electrically conductive material such as, for example, polysilicon or amorphous silicon is filled into the through-holes TH2 and the spaces made between the multiple first conductive films 54a. Thereby, the second conductive films 54b are formed between the multiple first conductive films 54a. In other words, the inter-layer conductive unit 54, which is electrically isolated from the memory region MU by the separation member 53, is provided in the non-memory region PR10. Thereby, the nonvolatile semiconductor memory device 140 is fabricated.

Although the embodiments described above are examples in which the nonvolatile semiconductor memory device mainly includes a NAND string having a U-shaped configuration in which two semiconductor pillars are connected by a connection portion, this may be applied also to a nonvolatile semiconductor memory device which has no connection portion and includes NAND strings having I-shaped configurations in which each of the semiconductor pillars is independent.

In the nonvolatile semiconductor memory device according to the embodiment, the inter-electrode insulating films 14, the inner insulating film 42, and the outer insulating film 43 may include a single-layer film of one selected from the group consisting of silicon oxide, silicon nitride, silicon oxynitride, aluminum oxide, aluminum oxynitride, hafnia, hafnium aluminate, hafnia nitride, hafnium nitride aluminate, hafnium silicate, hafnium nitride silicate, lanthanum oxide, and lanthanum aluminate or a stacked film made of a plurality selected from the group.

The charge storage film 48 includes a single-layer film of one selected from the group consisting of silicon nitride, silicon oxynitride, aluminum oxide, aluminum oxynitride, hafnia, hafnium aluminate, hafnia nitride, hafnium nitride aluminate, hafnium silicate, hafnium nitride silicate, lanthanum oxide, and lanthanum aluminate or a stacked film made of a plurality selected from the group.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the invention is not limited to these specific examples. For example, one skilled in the art may similarly practice the invention by appropriately selecting specific configurations of components such as semiconductor substrates, electrode films, insulating films, insulating layers, stacked structural bodies, memory layers, charge storage films, semiconductor pillars, word lines, bit lines, source lines, interconnects, memory cell transistors, selection gate transistors, etc., included in nonvolatile semiconductor memory devices from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all nonvolatile semiconductor memory devices practicable by an appropriate design modification by one skilled in the art based on the nonvolatile semiconductor memory devices described above as embodiments of the invention also are within the scope of the invention to the extent that the purport of the invention is included.

Furthermore, various modifications and alterations within the spirit of the invention will be readily apparent to those skilled in the art. All such modifications and alterations should therefore be seen as within the scope of the invention. For example, additions, deletions, or design modifications of components or additions, omissions, or condition modifications of processes appropriately made by one skilled in the art in regard to the embodiments described above are within the scope of the invention to the extent that the purport of the invention is included.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile semiconductor memory device, comprising:
a memory region including
a stacked structural body including a plurality of electrode films stacked alternately along a first direction with a plurality of inter-electrode insulating films,
a semiconductor pillar piercing the stacked structural body in the first direction,
a memory layer provided between the semiconductor pillar and each of the plurality of electrode films,
an inner insulating film provided between the memory layer and the semiconductor pillar, and
an outer insulating film provided between the memory layer and each of the plurality of electrode films; and
a non-memory region provided with the memory region along a second direction orthogonal to the first direction, the non-memory region including an insulating part provided at a position along the first direction being same as a position of at least one of the electrode films of the stacked structural body.

2. The device according to claim 1, wherein the insulating part includes a thermal oxide film formed by heating an electrically conductive layer including a material being same as a material of the plurality of electrode films.

3. The device according to claim 1, wherein the insulating part includes a first insulating film provided at the position along the first direction being same as the position of the electrode film.

4. The device according to claim 2, wherein the insulating part includes a second insulating film provided at a position along the first direction being same as a position of the inter-electrode insulating film.

5. The device according to claim 3, wherein
the insulating part includes a second insulating film provided at a position along the first direction being same as a position of the inter-electrode insulating film,
the first insulating film is provided at a position along the first direction being same as a position of each of the plurality of electrode films, and
the second insulating film is provided at a position along the first direction being same as a position of each of the plurality of inter-electrode insulating films.

6. The device according to claim 3, wherein the first insulating film includes a thermal oxide film formed by heating an electrically conductive layer including a material being same as a material of the electrode film.

7. The device according to claim 1, wherein the non-memory region further includes a conductive through-member piercing the insulating part along the first direction.

8. The device according to claim 7, further comprising:
a semiconductor substrate, the memory region and the non-memory region being provided in the semiconductor substrate; and
a peripheral region circuit provided in the semiconductor substrate,
the conductive through-member being electrically connected to the peripheral region circuit.

9. The device according to claim 1, wherein
the non-memory region further includes:
a conductive through-member piercing the insulating part along the first direction; and
a third insulating film provided between the insulating part and the conductive through-member.

10. The device according to claim 9, further comprising:
a semiconductor substrate, the memory region and the non-memory region being provided in the semiconductor substrate; and
a peripheral region circuit provided in the semiconductor substrate,
the conductive through-member being electrically connected to the peripheral region circuit.

11. The device according to claim 1, wherein the electrode film includes a material that becomes silicon oxide when heated.

12. The device according to claim 1, wherein the electrode film includes polysilicon.

13. The device according to claim 1, wherein
the memory region further includes:
a plurality of the semiconductor pillars; and
a connection portion to connect the plurality of semiconductor pillars.

14. A nonvolatile semiconductor memory device, comprising:
a memory region including
a stacked structural body including a plurality of electrode films stacked alternately along a first direction with a plurality of inter-electrode insulating films,
a semiconductor pillar piercing the stacked structural body in the first direction,
a memory layer provided between the semiconductor pillar and each of the plurality of electrode films,
an inner insulating film provided between the memory layer and the semiconductor pillar, and
an outer insulating film provided between the memory layer and each of the plurality of electrode films;
a non-memory region provided with the memory region along a second direction orthogonal to the first direction, the non-memory region including an inter-layer conductive unit provided at a position along the first direction being same as a position of at least one of the inter-electrode insulating films of the stacked structural body; and
a separation member provided between the memory region and the non-memory region to electrically isolate the plurality of electrode films from the inter-layer conductive unit.

15. The device according to claim 14, wherein the electrode film includes a material that becomes silicon oxide when heated.

16. The device according to claim 14, wherein the electrode film includes polysilicon.

17. The device according to claim 14, wherein
the memory region further includes:
a plurality of the semiconductor pillars; and
a connection portion to connect the plurality of semiconductor pillars.

18. A method for manufacturing a nonvolatile semiconductor memory device, comprising:
forming a stacked structural body on a major surface of a substrate in a first region on the major surface of the substrate and in a second region inside the first region, the stacked structural body including a plurality of first conductive films alternately stacked with a plurality of first films;
forming a support member to support the plurality of first conductive films by making a trench along a stacking direction of the stacked structural body at a boundary between the first region and the second region to pierce through to a position lower than an upper face of the first conductive film of a lowermost level of the stacked structural body and by filling an insulating material into the trench;
removing the plurality of first films in the second region;
oxidizing the plurality of first conductive films in the second region; and
making a through-hole to pierce in the stacking direction in the first region and forming an outer insulating film, a memory layer, and an inner insulating film in order on an inner wall of the through-hole.

19. The method according to claim 18, wherein the oxidizing of the plurality of first conductive films performs oxidization by heat treatment.

20. The device according to claim 18, wherein the plurality of first conductive film include polysilicon.
